(19) United States
(12) Patent Application Publication
(10) Pub. No.: US 2005/0051296 A1
(43) Pub. Date: Mar. 10, 2005

(54) Heat sink

(75) Inventor: Ching-Fa Shiao, Taipei County (TW)

Correspondence Address: BACON & THOMAS, PLLC, 625 SLATERS LANE, FOURTH FLOOR, ALEXANDRIA, VA, 22314, US

(73) Assignee: Ching-Fa Shiao, Taipei County (TW)

(21) Appl. No.: 10/715,567

(22) Filed: Nov. 19, 2003

(30) Foreign Application Priority Data
Sep. 30, 2002 (TW) 91215472

(51) Int. Cl. H05K 7/20

(52) U.S. Cl. 165/78; 165/80.3; 361/704

(57) ABSTRACT

A heat sink assembly for use within the cases of industrial computers, comprises a plurality of heat dissipating fins. Each heat dissipating fin comprises a body plate, and a pair of horizontal portions extending from the body plate. On each end of the horizontal portion is a slot, from where a protrusion protrudes. The protrusion is designed to be able to engage into the slot. Furthermore, from the protrusion extends a fastener. The fastener is employed such that adjacent heat sinks are fastened securely to each other so as to form a heat sink assembly of the present invention. In this way, the heat sink assembly of the present invention is finished with one single production process, thus providing with the advantages of simple process, easy-to-assembly as well as cost reduction.

### BACKGROUND OF THE INVENTION

1. Field of the Invention

The present invention relates to a heat sink assembly for use in industrial computers, more particularly, to a heat sink assembly composed of heat dissipating fins having fasteners. Each heat dissipating fin has an extension of a fastener which causes two adjacent heat dissipating fins to be mutually engaged so as to form a heat sink assembly for use in an electronic component.

2. Description of the Related Art

Within the case of industrial computers are many ICs, transistors, power electronic components, or CPUs. With the advance of technology, these electronic components work with high speed. Meanwhile, they also generate large amount of heat. Because the silicon chips and delicate metal wires within such electronic components are subject to damage under high temperature, a device is required to remove heat from such electronic components and the heat sink assembly serves the function well as a heat dissipation device.

A conventional heat dissipation device, shown in FIGS. 4(A) and 4(B), comprises a base plate 40 and a heat dissipating fin structure 70. The base plate 40, with an upper flat surface 41 and a lower flat surface 42, is made of aluminum; the heat dissipating fin structure 70 is made of a thin sheet that is stamped to form a plurality of inverted U-shaped fin modules. The upper flat surface 41 of the base plate 40 is soldered to the surface of the heat dissipating fin structure 70 having the plurality of inverted U-shaped fin modules, via tin film or tin paste, so as to form integrally as a heat dissipation device. After the base plate 40 and the heat dissipation plate 70 are assembled altogether, the lower flat surface 42 of the base plate 40 is placed upon a CPU (not shown in the diagrams), such that heat caused by the operation of the CPU will be transferred, via the base plate 40, to the heat dissipating fin 70 for heat dissipation.

However, the production of the conventional heat sink, that is to stamp a plurality of inverted U-shaped fin modules, is complicated and difficult. In addition, any error occurring during production renders a heat sink useless and causes a waste of cost.

### SUMMARY OF THE INVENTION

The object of the present invention is to provide a heat sink assembly for use in industrial computers. Such heat sink assembly comprises separate heat dissipating fins with fasteners and through fastening each heat dissipating fin by its fastener, such heat sink assembly serves the function of heat dissipation for electronic devices. Its production requires merely a single manufacturing process and is easy to assemble, therefore, resulting in the decrease of production cost.

To achieve the above-mentioned object, a heat sink assembly comprises multiple heat dissipating fins. Each heat dissipating fin includes a body plate and a pair of horizontal portions which are extensions of the body plate and are at right angles with the body plate. Each horizontal portion includes at least a slot from where a protrusion is extended. Extending from the protrusion is a fastener. By engaging the fastener to the slot, adjacent heat dissipating fins are fastened together to form a heat sink assembly.

A heat sink assembly can be assembled according to required number of heat sinks.

### BRIEF DESCRIPTION OF THE DRAWINGS

These and other features, aspects and advantages of the present invention will become better understood with regard to the following description, appended claims and accompanying drawings that are provided only for further elaboration without limiting or restricting the present invention, where:

FIG. 1 shows a bottom plan structural view of a heat sink assembly of the present invention.

FIG. 2 is a sectional view along the line X-X in FIG. 1, showing the incorporation of two heat dissipating fins.

FIG. 3 is a schematic diagram, showing the heat sink assembly of the present invention jointed with a base plate to form a heat dissipation device.

FIG. 4 is a structural diagram of a conventional heat dissipation device.

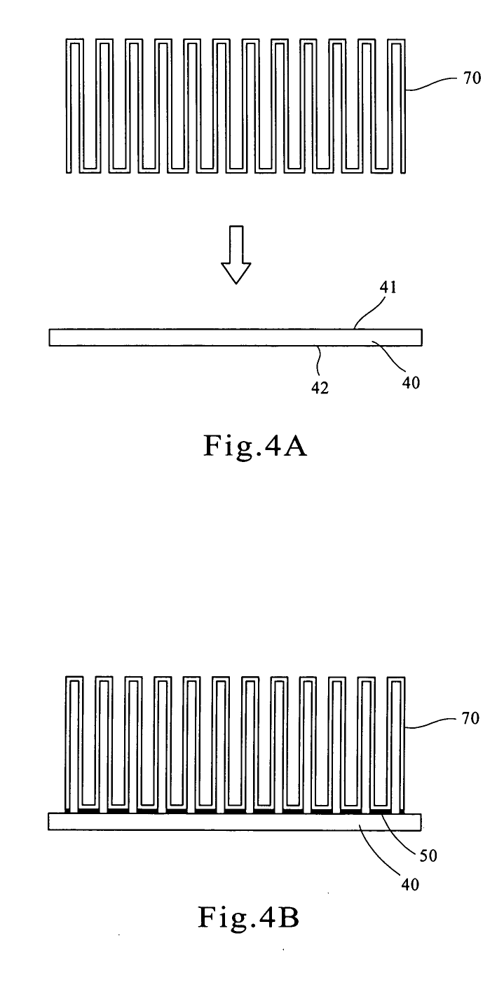

### DETAILED DESCRIPTION OF THE PREFERRED EMBODIMENT

The following is a detailed description of the best presently known modes of carrying out the inventions. This description is not to be taken in a limiting sense, but is made merely for the purpose of illustrating the general principles of the inventions.

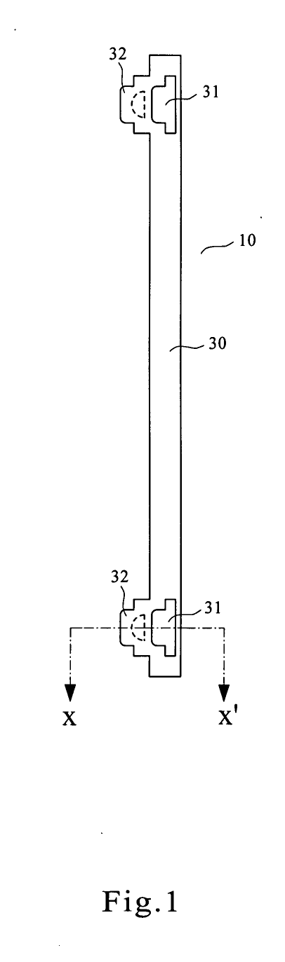

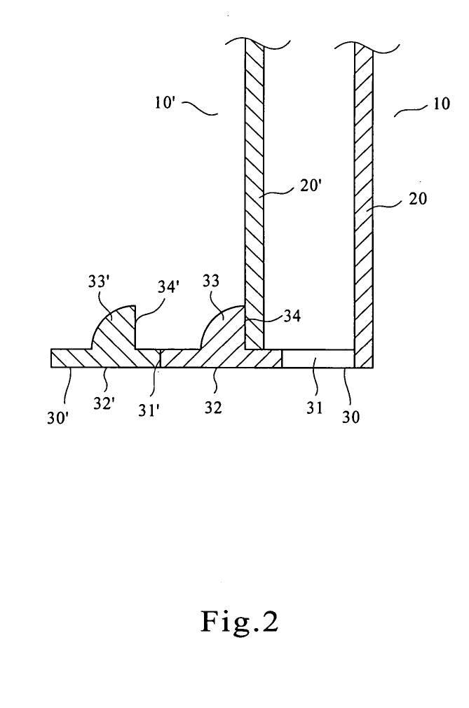

FIG. 1 is a top plan view of the heat sink assembly, showing that the heat sink assembly 100 of the present invention comprises multiple heat dissipating fins 10, and each heat dissipating fin 10 has the same structure, including a body plate 20 (Please refer to FIG. 2), a pair of corresponding horizontal portions 30 extending from the body plate 20 and at right angles with the body plate 20. At each end of the horizontal portions 30 is a slot 31. Extending from the slot 31 is a protrusion 32 with the shape thereof corresponding to that of the slot 31. A fastener 31 is located at the front end of the protrusion 32.

To facilitate the explication, FIG. 2 only demonstrates the first heat dissipating fin 10 and the second heat dissipating fin 10′ which both share the same structure. To assemble the first heat dissipating fin 10 with the second heat dissipating fin 10′, the protrusion 32 extending from the horizontal portions 30 of the first heat dissipating fin 10 is engaged into the slot 31′ extending from the horizontal portions 30′ of the second heat dissipating fin 10′, whereas the fastener 33 extending from the protrusion 32 of the first heat sink is engaged into the slot 31′ of the second heat dissipating fin 10′. Thus the first heat dissipating fin 10 and the second heat dissipating fin 10′ are fastened tightly. A wall 34 of the fastener 33 of the first heat dissipating fin 10 is in contact with the inner side of the body plate 20′ of the second heat dissipating fin 10′, such that the first heat dissipating fin 10 is fastened securely to the second heat dissipating fin 10′ via the fastener 33. By repeating this step, the fastener 33′ of the second heat dissipating fin 10′ is engaged to the slot of another heat dissipating fin. Thus a heat sink assembly 100 of the present invention is formed.

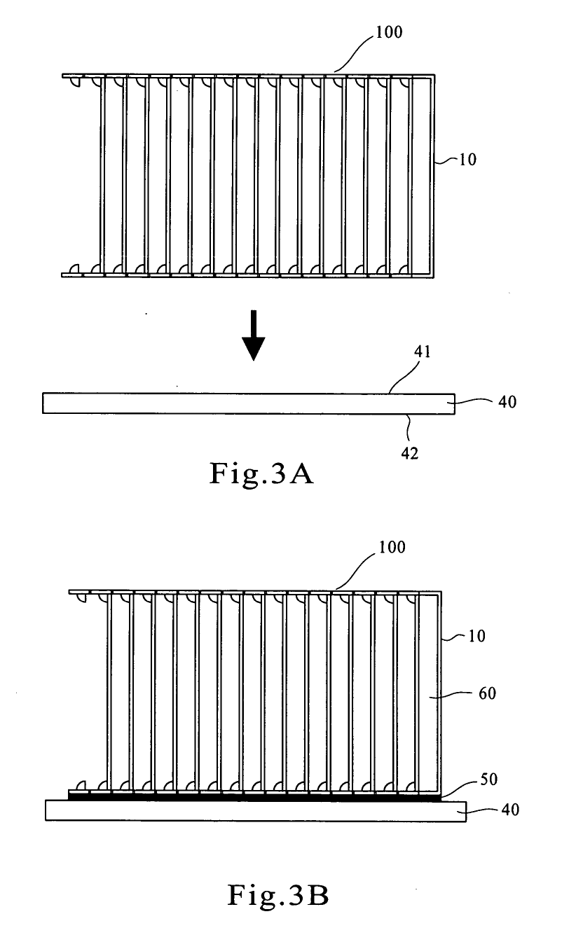

FIGS. 3(A) and 3(B) are schematic diagrams showing a heat sink assembly 100 of the present invention being incorporated with a base plate 40 so as to form a heat dissipation device. The base plate 40 having an upper surface 41 and a lower surface 42 is made of aluminum. To form a heat dissipation device, the upper surface 41 of the base plate 40 is soldered to the corresponding surface of the heat sink assembly 100 via tin film or tin paste. After the assembling of the base plate 40 and the heat sink assembly 100, the lower surface 42 of the base plate 40 is mounted on a central processing unit (not shown in the diagram), such that heat generated by the operation of a CPU will be transmitted to the heat dissipating fins 10 for dissipation. While assembling, the distance between the slot 31 on the horizontal portion 30 and the protrusion 32 protruding from the slot forms a space 60 between each heat dissipating fin 10. When the heat generated by the operation of the CPU is transmitted to the heat sink assembly 100, a fan (not shown in the diagrams) located on the front side of the spaces of the heat sink assembly 100 is utilized for providing air movement so as to cool the heat of the heat dissipating fin 10. The flow of air through the space 60 also facilitates the heat dissipation of the heat dissipating fins 10.

The present invention is manufactured by assembling each individual heat dissipating fin equipped with a fastener to form a heat dissipation device for use in electronic components. Only one single production process is involved, which is simple and easy to assemble and efficiently lowers the cost of production.

Although the present invention has been described in considerable detail with reference to certain preferred embodiments thereof, those skilled in the art can easily understand that all kinds of alterations and changes can be made within the spirit and scope of the appended claims. Therefore, the spirit and scope of the appended claims should not be limited to the description of the preferred embodiments contained herein.

1. A heat sink assembly comprising:
a plurality of heat dissipating fins with each said heat dissipating fin including:
a body plate; and
a pair of corresponding horizontal portions;
wherein said horizontal portions being formed by extending from both ends of said body plate and being perpendicular to said body plate, each said horizontal portion comprising at least one slot wherefrom a protrusion being extended, a fastener being extended downwardly from said protrusion, adjacent said heat dissipating fins being fastened to form a heat sink assembly via said slot and said fastener of said protrusion.

2. A heat sink assembly as in claim 1, wherein said heat sink assembly is formed according to the number of said heat dissipating fin required.
